(19) United States
(12) Patent Application Publication
(10) Pub. No.: US 2023/0025927 A1
(43) Pub. Date: Jan. 26, 2023

(54) VAPOR DEPOSITION DEVICE

(71) Applicant: SUMCO CORPORATION, Tokyo (JP)

(72) Inventor: Yu MINAMIDE, Tokyo (JP)

(73) Assignee: SUMCO CORPORATION, Tokyo (JP)

(21) Appl. No.: 17/788,231

(22) PCT Filed: Oct. 15, 2020
(86) PCT No.: PCT/JP2020/038899

§ 371 Date: Jun. 22, 2022

(30) Foreign Application Priority Data
Dec. 25, 2019 (JP) 2019-234059

(51) Int. Cl. H01L 21/68; H01L 21/687; H01L 21/677; C23C 16/54; C23C 16/458; C23C 16/24; C30B 25/12; C30B 29/06

(52) U.S. Cl. CPC H01L 21/68; H01L 21/68785; H01L 21/67763; H01L 21/67739; C23C 16/54; C23C 16/4584; C23C 16/24; C30B 25/12; C30B 29/06

(57) ABSTRACT

A vapor deposition device is provided that can correct a positional offset of a carrier in a rotation direction relative to a wafer when the vapor deposition device is viewed in a plan view. The vapor deposition device includes a load-lock chamber provided with a holder for supporting the carrier, and the carrier and the holder are provided with a correction mechanism that corrects a position of the carrier in a rotation direction when the vapor deposition device is viewed in a plan view.

### FIELD OF THE INVENTION

The present invention relates to a vapor deposition device used in manufacturing epitaxial wafers, for example.

### BACKGROUND OF THE INVENTION

In a load-lock chamber of a multi-chamber processing system for depositing a film on a substrate, using a positioning mechanism such as an alignment ring and an alignment pin to align a position of the substrate relative to a carrier that transfers the substrate is known (Patent Literature 1).

### RELATED ART

### Patent Literature

Patent Literature 1: Specification of U.S. Pat. No. 9,929,029

### SUMMARY OF THE INVENTION

### Problems to be Solved by the Invention

When the vapor deposition device is viewed in a plan view, the positioning mechanism aligns to a position based on the position of the carrier in vertical as well as left and right directions relative to the substrate (wafer), but does not correct the position of the wafer in a rotation direction. In order to deposit a uniform film on the wafer, when the carrier has a shape that changes periodically in the rotation direction of the wafer, the position of the carrier in the rotation direction relative to the wafer is not aligned, which negatively affects quality of a treated wafer. However, in the conventional technology mentioned above, nothing is disclosed about correcting a position of the carrier in the rotation direction relative to the wafer when the vapor deposition device is viewed in plan view.

The present invention undertakes to solve the issue of providing a vapor deposition device that can correct a positional offset of the carrier in the rotation direction relative to the wafer when the vapor deposition device is viewed in plan view.

### Means for Solving the Problems

The present invention is a vapor deposition device which uses a ring-shaped carrier that supports the wafer to form a CVD film on the wafer, the vapor deposition device includes a load-lock chamber provided with a holder for supporting the carrier, and the carrier and the holder are provided with a correction mechanism that corrects the position of the carrier in the rotation direction along a circumferential direction of the wafer.

In the present invention, the correction mechanism more preferably includes a pair of correction mechanisms to regulate a clockwise rotation and a counterclockwise rotation of the carrier.

In the present invention, the correction mechanism more preferably includes, when the device is viewed in a plan view, a correction mechanism that corrects the position of the carrier in the vertical direction as well as the left and right direction.

In the present invention, the correction mechanism more preferably includes a first engagement portion provided to the carrier and a second engagement portion provided to the holder.

In the present invention, the second engagement portion more preferably includes an engagement surface that engages with the first engagement portion, a rotation surface that rotates the carrier relatively to the holder, and a positioning surface that determines a correction position of the carrier relative to the holder.

In the present invention, the first engagement portion more preferably includes an engagement surface that engages with the second engagement portion, a rotation surface that rotates the carrier relatively to the holder, and a positioning surface that determines a correction position of the carrier relative to the holder.

In the present invention, the engagement surface and the rotation surface are more preferably configured to be on the same plane.

In the present invention, the holder supports at least two carriers vertically and more preferably, the correction mechanism is not provided to a topmost-level holder.

In the present invention, the CVD film is more preferably a silicon epitaxial film.

In the present invention, more preferably, a plurality of before-treatment wafers are transported from a wafer storage container, through a factory interface, load-lock chamber, and wafer transfer chamber, to a reaction chamber that forms the CVD film on the wafer, in that order; a plurality of after-treatment wafers are also transported from the reaction chamber, through the wafer transfer chamber, load-lock chamber, and factory interface, to the wafer storage container, in that order; the load-lock chamber communicates with the factory interface via a first door and also communicates with the wafer transfer chamber via a second door; the wafer transfer chamber communicates with the reaction chamber via a gate valve; the wafer transfer chamber is provided with a first robot that deposits a before-treatment wafer transported into the load-lock chamber into the reaction chamber in a state where the before-treatment wafer is supported by a carrier and also, for an after-treatment wafer for which treatment in the reaction chamber has ended, withdraws the after-treatment wafer from the reaction chamber in a state where the after-treatment wafer is supported by the carrier and transports the wafer to the load-lock chamber; the factory interface is provided with a second robot that extracts the before-treatment wafer from the wafer storage container and supports the wafer with the carrier that is standing by in the load-lock chamber, and also stores in the wafer storage container the after-treatment wafer supported by the carrier that has been transported to the load-lock chamber; and the load-lock chamber is provided with a holder for supporting the carrier.

### Effect of the Invention

According to the present invention, when the vapor deposition device is viewed in a plan view, in the holder for supporting the carrier, the position of the carrier in the rotation direction along the circumferential direction of the wafer is corrected. Accordingly, a positional offset of the carrier in the rotation direction relative to the wafer can be corrected.

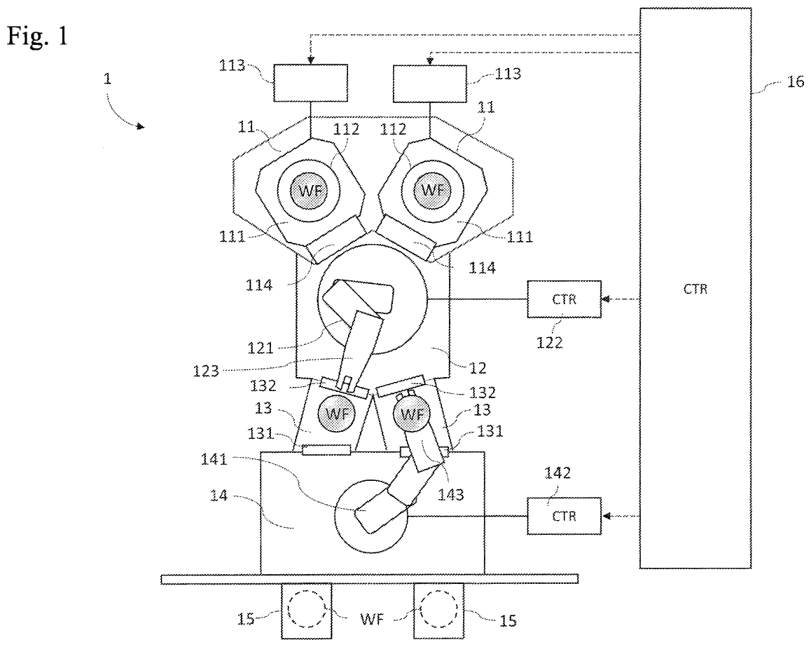

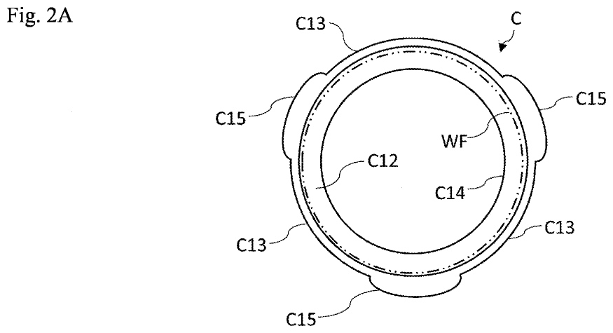

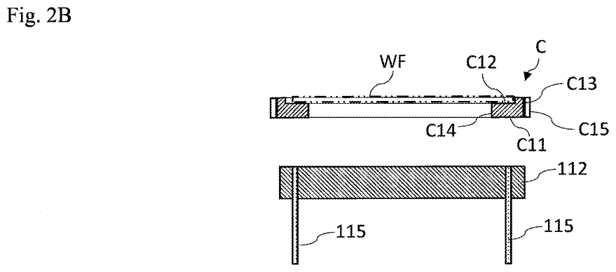

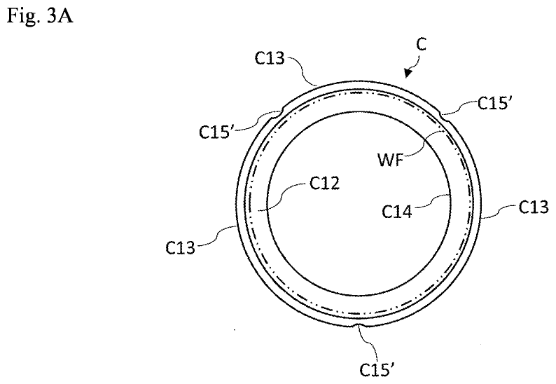

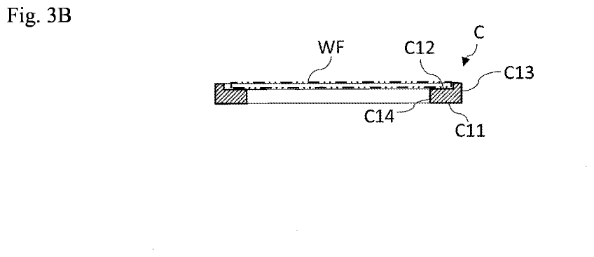

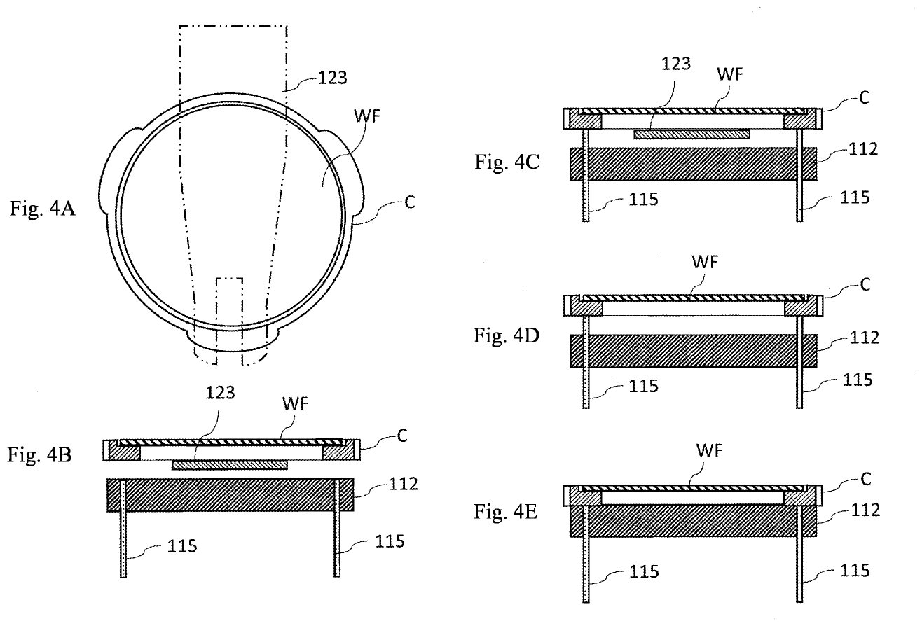

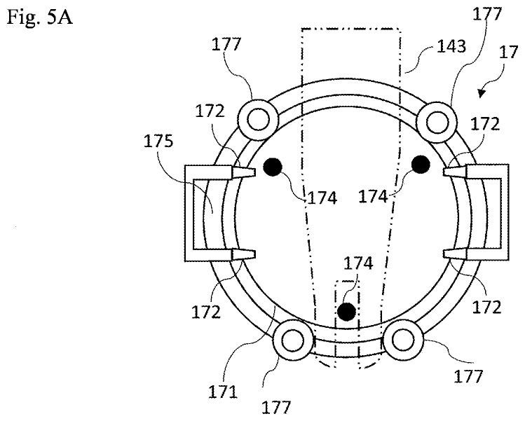

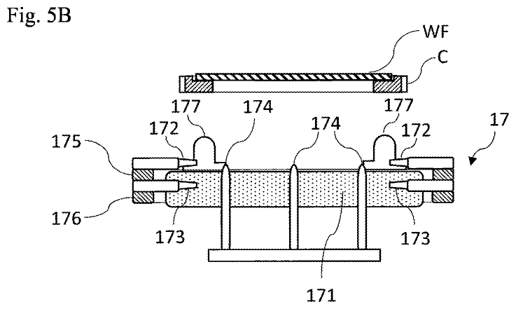

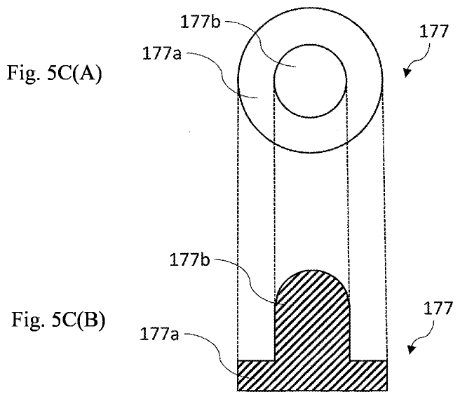

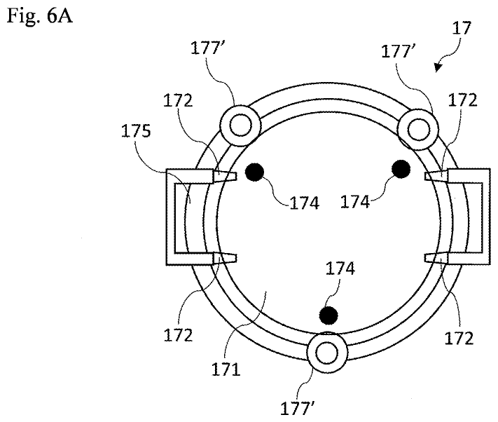

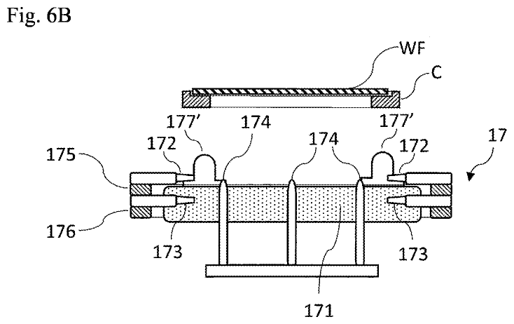

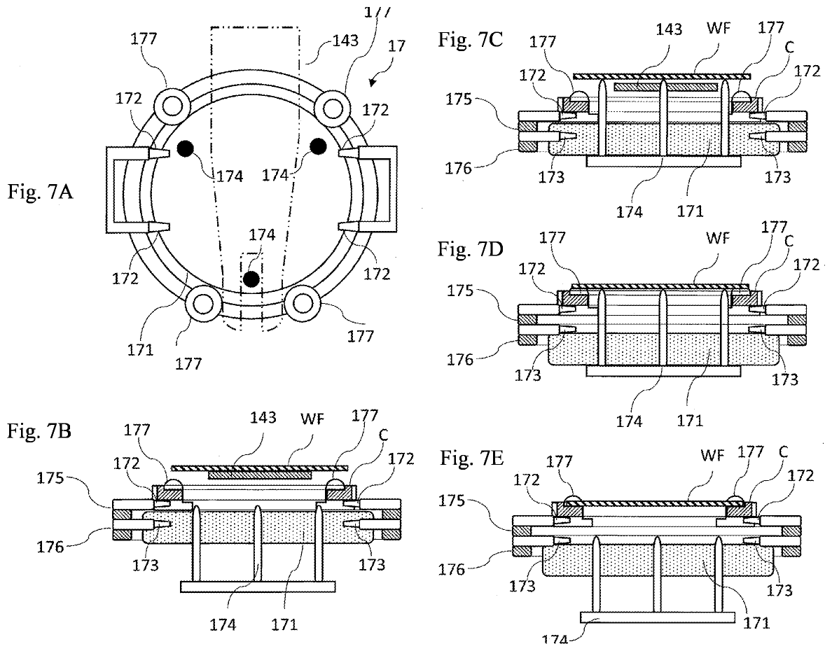

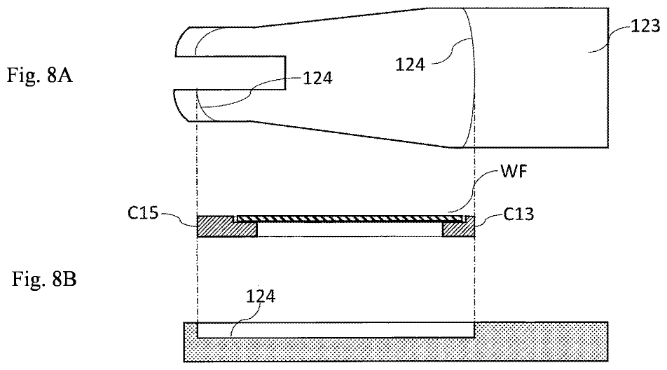

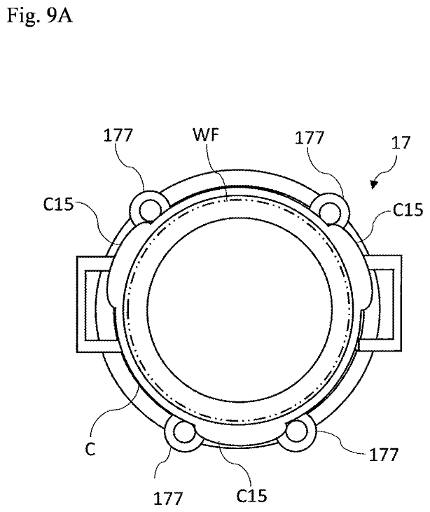

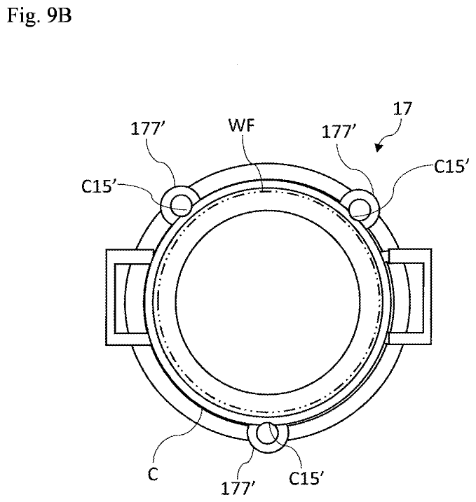

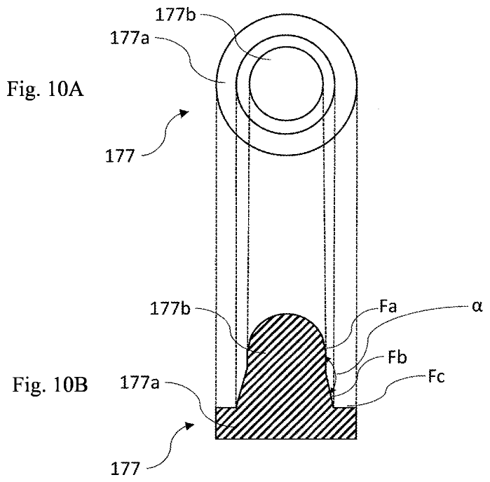

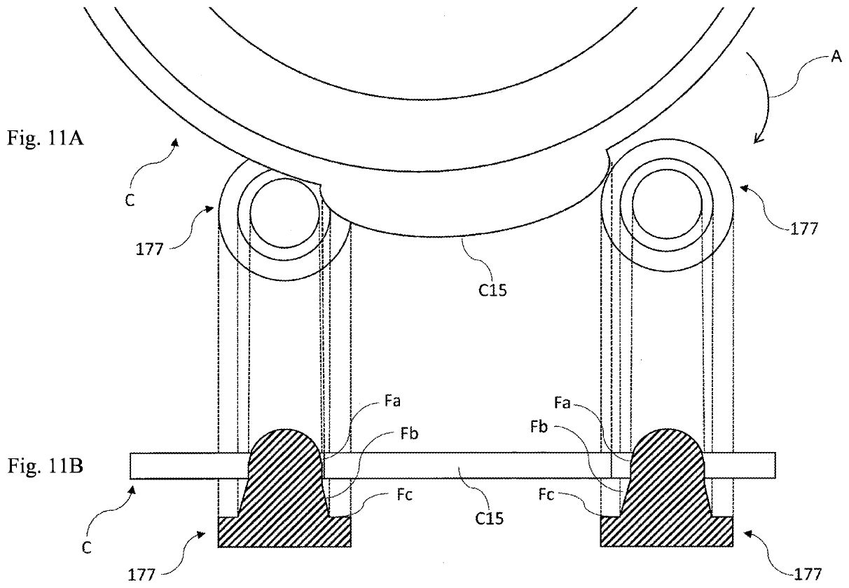

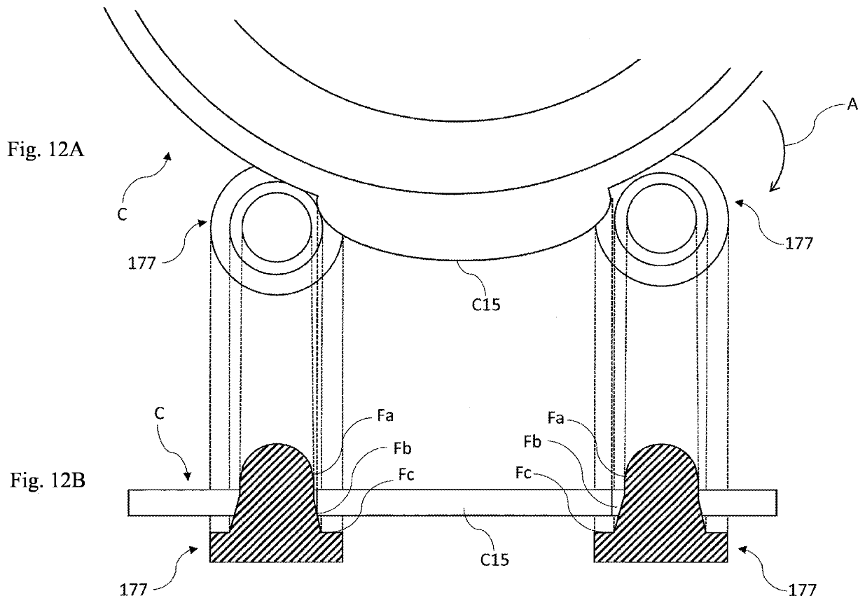

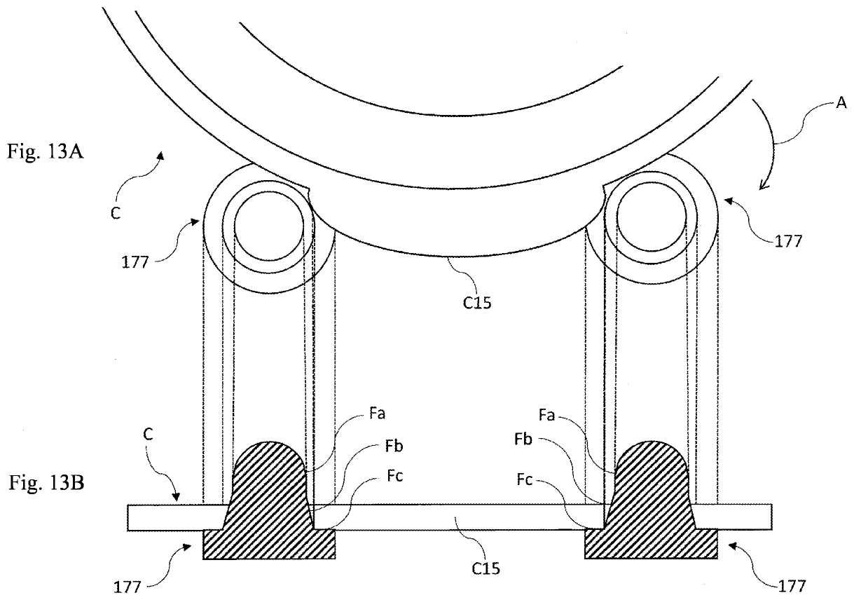

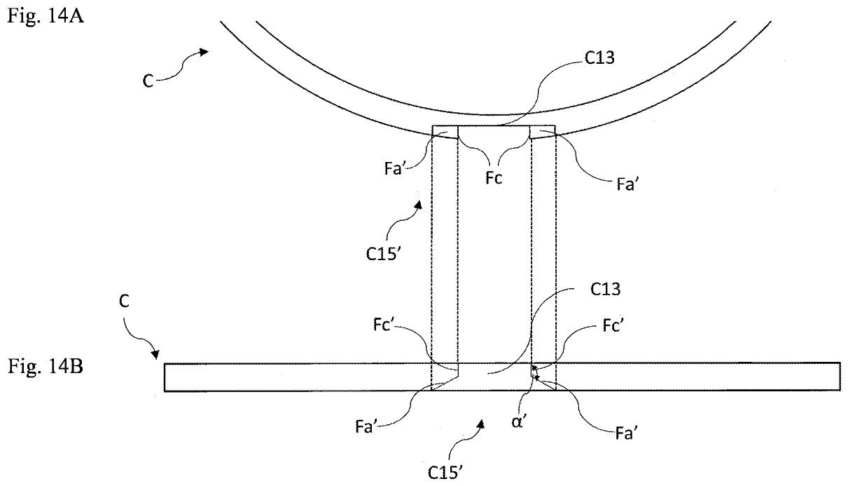

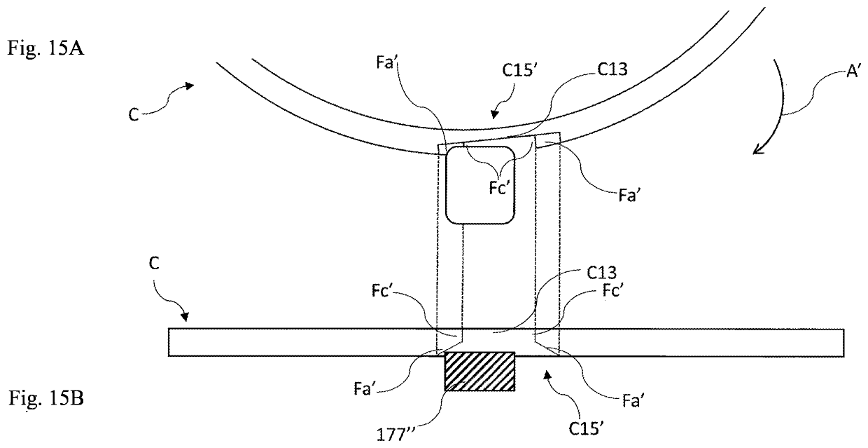

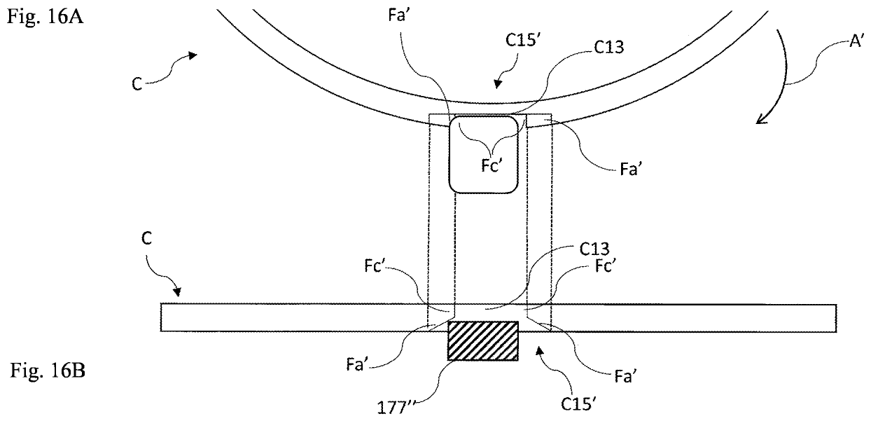

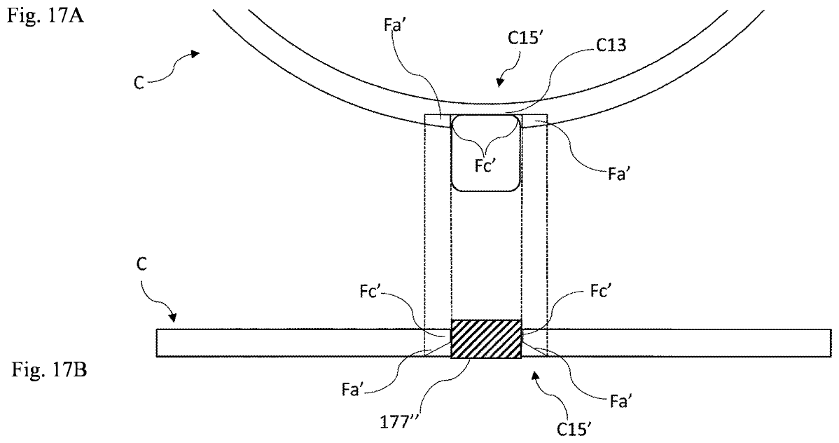

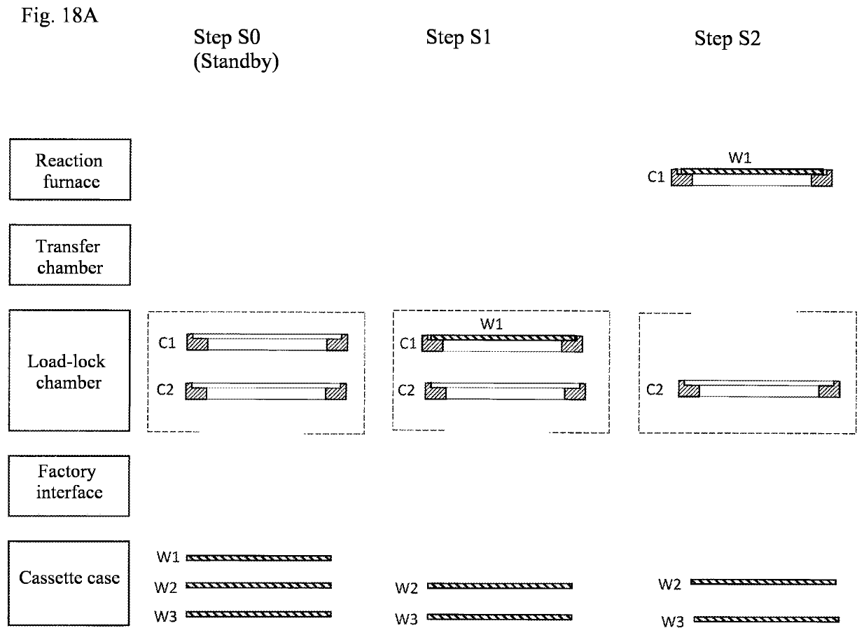

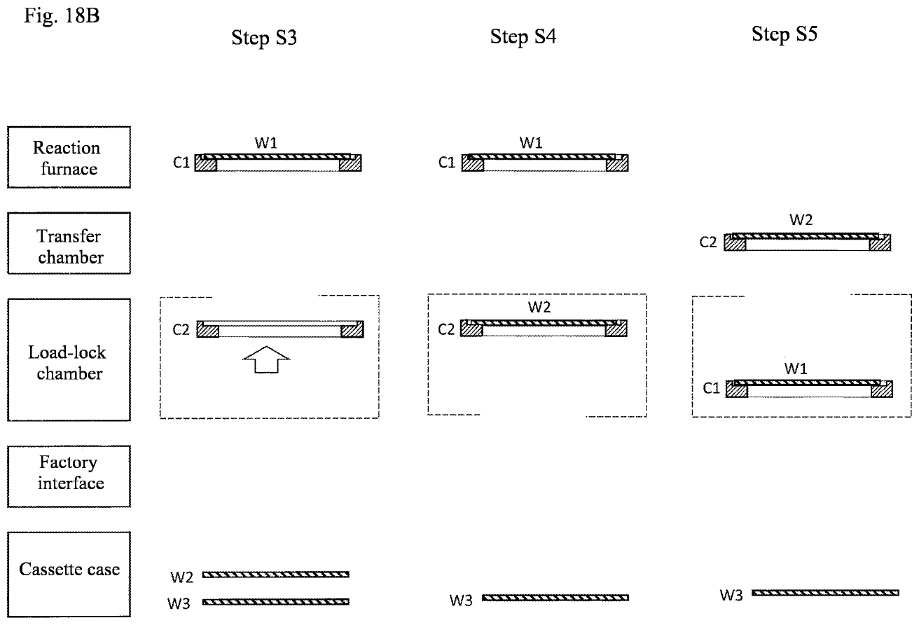

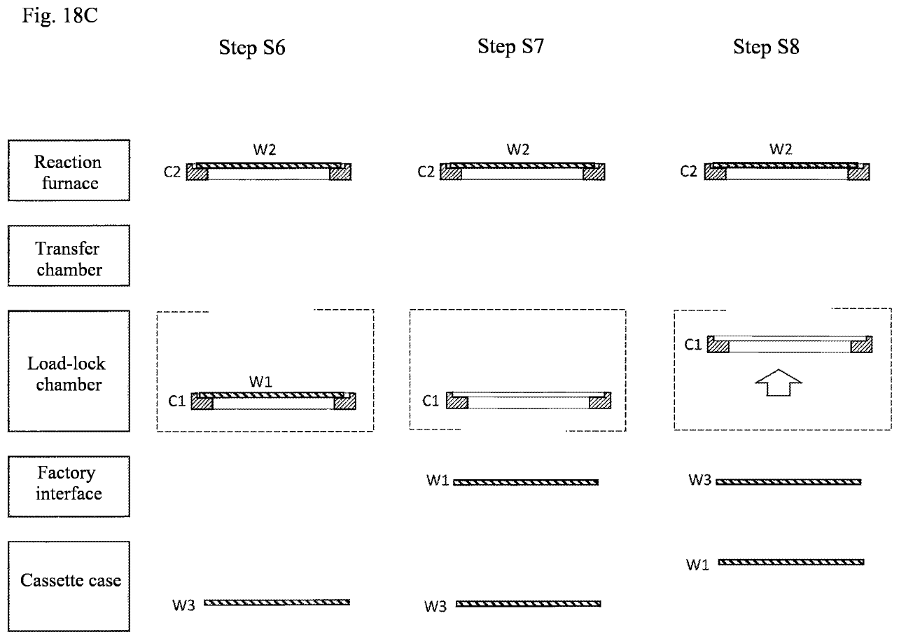

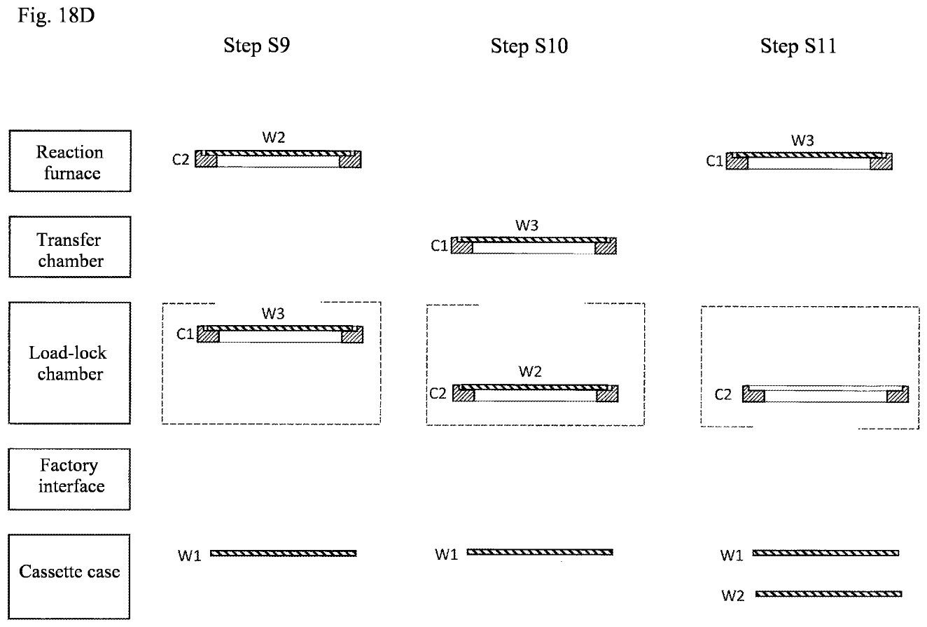

### BRIEF DESCRIPTION OF THE DRAWINGS

[FIG. 1] is a block diagram illustrating a vapor deposition device according to an embodiment of the present invention.

[FIG. 2A] is a plan view illustrating an exemplary carrier and first engagement portion provided to the carrier according to the embodiment of the present invention.

[FIG. 2B] is a vertical cross-sectional view of the carrier in FIG. 2A, including a wafer and a susceptor of a reaction furnace in the vapor deposition device of FIG. 1.

[FIG. 3A] is a plan view illustrating another exemplary carrier and first engagement portion provided to the carrier according to the embodiment of the present invention.

[FIG. 3B] is a vertical cross-sectional view of the carrier in FIG. 3A, including the wafer and the susceptor of the reaction furnace in the vapor deposition device of FIG. 1.

[FIG. 4] is a plan view and vertical cross-sectional views illustrating a transfer protocol for the wafer and carrier within a reaction chamber in the vapor deposition device of FIG. 1.

[FIG. 5A] is a plan view illustrating an exemplary holder provided to a load-lock chamber in the vapor deposition device of FIG. 1.

[FIG. 5B] is a vertical cross-sectional view of the holder in FIG. 5A, including the wafer and the carrier in the vapor deposition device of FIG. 1.

[FIG. 5C] FIG. 5C(A) is a plan view illustrating a second engagement portion provided to the carrier in FIG. 5A, and FIG. 5C(B) is a vertical cross-sectional view.

[FIG. 6A] is a plan view illustrating another exemplary holder provided to the load-lock chamber in the vapor deposition device of FIG. 1.

[FIG. 6B] is a vertical cross-sectional view of the holder in FIG. 6A, including the wafer and the carrier in the vapor deposition device of FIG. 1.

[FIG. 7] is a plan view and vertical cross-sectional views illustrating the transfer protocol for the wafer and carrier in the load-lock chamber in the vapor deposition device of FIG. 1.

[FIG. 8] FIG. 8A is a plan view illustrating an exemplary first blade mounted on a distal end of a first robot hand in the vapor deposition device of FIG. 1, and FIG. 8B is a vertical cross-sectional view of the first blade, including the carrier and the wafer in the vapor deposition device of FIG. 1.

[FIG. 9A] is a plan view illustrating the carrier and the holder when the carrier in FIG. 2A supporting the wafer is mounted on the holder in FIG. 5A.

[FIG. 9B] is a plan view illustrating the carrier and the holder when the carrier in FIG. 3A supporting the wafer is mounted on the holder in FIG. 6A.

[FIG. 10] is a plan view (FIG. 10A) and a vertical cross-sectional view (FIG. 10B) illustrating another exemplary second engagement portion provided to the holder in the load-lock chamber in the vapor deposition device 1 of FIG. 1.

[FIG. 11] is a plan view (FIG. 11A) and a vertical cross-sectional view (FIG. 11B) illustrating an exemplary positional correction of the carrier in a rotation direction using the first engagement portion of the carrier illustrated in FIG. 2A and the second engagement portion in FIG. 10 (no. 1).

[FIG. 12] is a plan view (FIG. 12A) and a vertical cross-sectional view (FIG. 12B) illustrating an exemplary positional correction of the carrier in the rotation direction using the first engagement portion of the carrier illustrated in FIG. 2A and the second engagement portion in FIG. 10 (no. 2).

[FIG. 13] is a plan view (FIG. 13A) and a vertical cross-sectional view (FIG. 13B) illustrating an exemplary positional correction of the carrier in the rotation direction using the first engagement portion of the carrier illustrated in FIG. 2A and the second engagement portion in FIG. 10 (no. 3).

[FIG. 14] is a plan view illustrating yet another exemplary first engagement portion provided to the carrier according to the embodiment of the present invention.

[FIG. 15] is a plan view (FIG. 15A) and a vertical cross-sectional view (FIG. 15B) illustrating another exemplary positional correction of the carrier in the rotation direction using the first engagement portion of the carrier illustrated in FIG. 14 and the second engagement portion corresponding to the first engagement portion (no. 1).

[FIG. 16] is a plan view (FIG. 16A) and a vertical cross-sectional view (FIG. 16B) illustrating another exemplary positional correction of the carrier in the rotation direction using the first engagement portion of the carrier illustrated in FIG. 14 and the second engagement portion corresponding to the first engagement portion (no. 2).

[FIG. 17] is a plan view (FIG. 17A) and a vertical cross-sectional view (FIG. 17B) illustrating another exemplary positional correction of the carrier in the rotation direction using the first engagement portion of the carrier illustrated in FIG. 14 and the second engagement portion corresponding to the first engagement portion (no. 3).

[FIG. 18A] is a diagram (no. 1) illustrating a handling protocol for the wafer and the carrier in the vapor deposition device of FIG. 1.

[FIG. 18B] is a diagram (no. 2) illustrating the handling protocol for the wafer and the carrier in the vapor deposition device of FIG. 1.

[FIG. 18C] is a diagram (no. 3) illustrating the handling protocol for the wafer and the carrier in the vapor deposition device of FIG. 1.

[FIG. 18D] is a diagram (no. 4) illustrating the handling protocol for the wafer and the carrier in the vapor deposition device of FIG. 1.

### MODE FOR CARRYING OUT THE INVENTION

Hereafter, an embodiment of the present invention is described with reference to the drawings. A vapor deposition device 1 is a device (i.e., CVD device) for supplying on a wafer WF a simple substance gas or one or more compound gases consisting of elements configuring a thin-film material, and for forming a desired thin film by a chemical reaction in a vapor phase or on a surface of the wafer WF. FIG. 1 is a block diagram in a plan view illustrating the vapor deposition device 1 according to the embodiment of the present invention. The vapor deposition device 1 of the present embodiment is provided with a pair of reaction furnaces 11, 11, a wafer transfer chamber 12, a pair of load-lock chambers 13, a factory interface 14, a load port on which is installed a wafer storage container 15 (cassette case) in which a plurality of the wafers WF are stored, and an integrated controller 16 that integrates control of the entire vapor deposition device 1.

The reaction furnace 11 is a device for forming a CVD film (silicon epitaxial film, for example) on a surface of a wafer WF such as a single crystal silicon wafer using the CVD method. The reaction furnace 11 includes a reaction chamber 111 that performs the chemical reaction forming a CVD film; a susceptor 112 on which the wafer WF is placed and rotated inside the reaction chamber 111; a gas supply device 113 that supplies to the reaction chamber 111 hydrogen gas and raw material gas for forming the CVD film, and a gate valve 114 to ensure airtightness of the reaction chamber 111. In addition, although omitted from the drawings, a heat lamp for raising the temperature of the wafer WF to a predetermined temperature is provided on the periphery of the reaction chamber 111. Activation and deactivation of the heat lamp are controlled by a command signal from the integrated controller 16. FIG. 1 shows the vapor deposition device 1 provided with the pair of reaction furnaces 11, 11, but the number of reaction furnaces is not particularly limited: there may be one reaction furnace or three or more reaction furnaces.

The reaction chamber 111 is a chamber provided to block outside air and maintain an atmosphere when performing the chemical reaction that forms the CVD film. The chamber for the reaction chamber 111 is not particularly limited.

The susceptor 112 is a support body of the wafer WF for placing and heating the wafer WF. In the vapor deposition device 1 of the present embodiment, the susceptor 112 is provided inside the reaction chamber 111 and places and rotates the wafer WF. By rotating the susceptor 112, a non-uniform CVD film can be prevented from forming on the surface of the wafer WF. The material of the susceptor is not particularly limited, but examples include carbon (C) coated with silicon carbide (SiC), ceramics such as SiC and SiO₂, and glassy carbon. The driving of the susceptor 112, including rotation and stoppage, is controlled by a command signal from the integrated controller 16.

The gas supply device 113 is a device that supplies, to the reaction chamber 111, gas such as hydrogen gas or raw material gas needed for the chemical reaction for forming the CVD film. When the CVD film is a silicon epitaxial film, a gas such as dichlorosilane (SiH₂Cl₂) and trichlorosilane (SiHCl₃) may be supplied. A method of supplying the gas is not particularly limited, and a known supply system can be used. The gas supplied to the reaction chamber 111 from the gas supply device 113 is replaced by hydrogen gas supplied by the gas supply device 113 after the reaction of the CVD film formation. The replaced post-reaction gas is cleaned by a scrubber (scrubbing dust collector) connected to an exhaust port provided to the reaction chamber 111 and is then released outside the system. Although a detailed depiction is omitted, this type of scrubber can use a conventionally known pressurized water scrubber, for example. The supply and stoppage of gas by the gas supply device 113, the operation of the scrubber, and the like are controlled by a command signal from the integrated controller 16.

The gate valve 114 is a valve for dividing the reaction chamber 111, the wafer transfer chamber 12, and the load-lock chamber 13 of the vapor deposition device 1. The gave valve 114 is provided between the reaction chamber 111 and the wafer transfer chamber 12. By closing the gate valve 114, airtightness between the wafer transfer chamber 12 and reaction chamber 111 is ensured. Opening and closing the gate valve 114 is controlled by a command signal from the integrated controller 16.

The wafer transfer chamber 12 is a sealed chamber for transporting the wafer WF from the load-lock chamber 13 to the reaction chamber 111 of the reaction furnace 11. The chamber for the wafer transfer chamber 12 is not particularly limited and a known chamber can be used. The wafer transfer chamber 12 is located between the reaction chamber 111 of the reaction furnace 11 and the load-lock chamber 13. The reaction chamber 111 of the reaction furnace 11 and the load-lock chamber 13 communicate via the wafer transfer chamber 12. One side of the wafer transfer chamber 12 is connected to the load-lock chamber 13 via an airtight second door 132 that can be opened and closed. In contrast, the other side of the wafer transfer chamber 12 is connected to the reaction chamber 111 via the gate valve 114 that has an airtight seal to allow opening and closing.

The wafer transfer chamber 12 includes a first robot 121 that handles the wafer WF. The first robot 121 transports the before-treatment wafer WF from the load-lock chamber 13 to the reaction chamber 111 and transports the after-treatment wafer WF from the reaction chamber 111 to the load-lock chamber 13. The first robot 121 is controlled by a first robot controller 122, and a first blade 123 mounted on a distal end of a robot hand displaces along an operation trajectory that has been taught in advance.

The wafer transfer chamber 12 includes an inert gas supply device not shown in the drawings. Inert gas is supplied from the inert gas supply device and the gas in the wafer transfer chamber 12 is replaced. The gas replaced by the inert gas is cleaned by the scrubber (scrubbing dust collector) connected to the exhaust port and is then released outside the system. Although a detailed depiction is omitted, this type of scrubber can use a conventionally known pressurized water scrubber, for example. The supply and stoppage of inert gas by the inert gas supply device, operation of the scrubber, and the like are controlled by a command signal from the integrated controller 16.

The load-lock chamber 13 serves as a space where atmospheric gas exchange takes place between the wafer transfer chamber 12 which is configured to have an inert gas atmosphere, and the factory interface 14 which is configured to have an air atmosphere. The load-lock chamber 13 is provided with a first door 131 having an airtight seal that allows opening and closing between the load-lock chamber 13 and the factory interface 14. On the other side, the load-lock chamber 13 is provided with the second door 132, which similarly has an airtight seal that allows opening and closing between the load-lock chamber 13 and the wafer transfer chamber 12. In other words, the factory interface 14 and the wafer transfer chamber 12 communicate via the load-lock chamber 13. When the first door 131 is opened, the load-lock chamber 13 becomes an air atmosphere. At this point, the first door 131 and the second door 132 are closed, and the air gas of the load-lock chamber 13 is replaced by the inert gas to provide the load-lock chamber 13 with an inert gas atmosphere. For the inert gas exchange, the load-lock chamber 13 includes an exhaust device that evacuates an interior of the load-lock chamber 13 to vacuum and a supply device that supplies inert gas to the load-lock chamber 13.

The factory interface 14 is a zone for transporting the wafer WF between the load-lock chamber 13 and the wafer storage container 15, and is configured to have the same air atmosphere as a clean room. The factory interface 14 includes a second robot 141 that handles the wafer WF. The second robot 141 extracts a before-treatment wafer WF that is stored in the wafer storage container 15 and deposits the wafer WF in the load-lock chamber 13, and also stores an after-treatment wafer WF transported to the load-lock chamber 13 in the wafer storage container 15. The second robot 141 is controlled by a second robot controller 142, and a second blade 143 mounted on a distal end of a robot hand displaces along a predetermined trajectory that has been taught in advance. The second blade 143 of the present embodiment is not particularly limited and a known blade that can transport the wafer WF can be used.

The wafer storage container 15 (cassette case) is a container for storing and transporting the wafer WF between devices and is placed in the same air atmosphere as a clean room. The load port in which the wafer storage container 15 is mounted is a part of the vapor deposition device 1 where the wafer storage container 15 (cassette case) is transferred to an external device for loading and unloading the wafer storage container 15. The wafer storage container 15 and the load port are not particularly limited.

The integrated controller 16 integrates control of the entire vapor deposition device 1. The integrated controller 16 mutually sends and receives control signals with the first robot controller 122 and the second robot controller 142. When an operation command signal from the integrated controller 16 is sent to the first robot controller 122, the first robot controller 122 controls the operation of the first robot 121. An operation result of the first robot 121 is sent from the first robot controller 122 to the integrated controller 16. Accordingly, the integrated controller 16 recognizes an operation status of the first robot 121. Similarly, when an operation command signal from the integrated controller 16 is sent to the second robot controller 142, the second robot controller 142 controls the operation of the second robot 141. An operation result of the second robot 141 is sent from the second robot controller 142 to the integrated controller 16. Accordingly, the integrated controller 16 recognizes an operation status of the second robot 141.

The vapor deposition device 1 of the present embodiment controls, by the integrated controller 16, each operation of the gate valve 114 dividing the reaction chamber 111 of the reaction furnace 11 from the wafer transfer chamber, the first door 131 dividing the load-lock chamber 13 from the factory interface 14, the second door 132 dividing the wafer transfer chamber 12 from the load-lock chamber 13, the first robot 121 that handles the wafer WF in the wafer transfer chamber 12, and the second robot 141 that handles the wafer WF in the factory interface 14, and thereby the wafer WF is transported in that order and CVD film formation treatment is performed inside the vapor deposition device 1.

For example, in the vapor deposition device 1 of the present embodiment, when transporting a before-treatment wafer WF from the wafer storage container 15 to the reaction chamber 111 of the reaction furnace 11, the first door 131 and the second door 132 are first closed to create a state where the load-lock chamber 13 has an inert gas atmosphere. Next, a wafer WF is extracted from the wafer storage container 15 using the second robot 141, the first door 131 is opened, and the wafer WF is transported to the load-lock chamber 13. Next, after the first door 131 is closed and the load-lock chamber 13 is restored to an inert gas atmosphere, the second door 132 is opened and the wafer WF is transported to the wafer transfer chamber 12 using the first robot 121. Lastly, the second door 132 is closed and the gate valve 114 is opened, and the wafer WF that was transported to the wafer transfer chamber 12 is transported to the reaction chamber 111 of the reaction furnace 11 using the first robot 121.

Conversely, in the vapor deposition device 1 of the present embodiment, when transporting the after-treatment wafer WF from the reaction chamber 111 of the reaction furnace 11 to the wafer storage container 15, the gate valve 114 is first opened and the after-treatment wafer WF on which the CVD film is formed is extracted from the reaction chamber 111 of the reaction furnace 11 using the first robot 121 and the gate valve 114 is closed. Next, the second door 132 is opened and the wafer WF in the wafer transfer chamber 12 is transported to the load-lock chamber 13 using the first robot 121. Lastly, after the second door 132 is closed and the load-lock chamber 13 is restored to an inert gas atmosphere, the first door 131 is opened and the wafer WF is stored in the wafer storage container 15 using the second robot 141.

In the vapor deposition device 1 of the present embodiment, when transporting the wafer WF between the reaction chamber 111 of the reaction furnace 11 and the load-lock chamber 13, a ring-shaped carrier C that supports the wafer WF is used. FIG. 2A is a plan view illustrating an exemplary carrier C of the present embodiment, and FIG. 2B is a vertical cross-sectional view of the carrier C of FIG. 2A, including the wafer WF and the susceptor 112 of the reaction furnace 11, when viewed in a front view.

The carrier C according to the present embodiment is configured by a material such as carbon coated with silicon carbide, ceramics such as SiC and SiO₂, or glassy carbon, for example, and is formed in a ring shape. The carrier C according to the present embodiment includes, for example, a bottom surface C11 that rests on a top surface of the susceptor 112 shown in FIG. 2B, a top surface C12 that touches and supports the outer periphery of a reverse face of the wafer WF, an outer circumferential wall surface C13, and an inner circumferential wall surface C14.

Further, when the vapor deposition device 1 according to the present embodiment is viewed in a plan view, the carrier C according to the present embodiment is provided with at least one correction mechanism that corrects the position of the carrier C in a rotation direction along a circumferential direction of the wafer WF. A first engagement portion C15 of FIG. 2A is an exemplary correction mechanism of the present embodiment. The first engagement portion C15 of FIG. 2A is a projection in a semi-elliptical shape provided to the outer circumferential wall surface C13. The shape of the correction mechanism of the present embodiment is not limited to the projection in the semi-elliptical shape as shown in FIG. 2A and may be a circular projection, a rectangular projection, or a convex shape, for example. The position where the correction mechanism is provided on the carrier C of the present embodiment is not limited to the outer circumferential wall surface C13 as shown in FIG. 2A, and may be the bottom surface C11 or the inner circumferential wall surface C14, for example.

In addition, FIG. 3A is a plan view illustrating another exemplary carrier C of the present embodiment, and FIG. 3B is a vertical cross-sectional view of the carrier C of FIG. 3A, including the wafer WF and the susceptor 112 of the reaction furnace 11, when viewed in a front view. A first engagement portion C15′ of FIG. 3A is another example of the correction mechanism of the present embodiment, and is a circular notch provided to the outer circumferential wall surface C13. The shape of the correction mechanism of the present embodiment is not limited to the circular notch as shown in FIG. 3A and may be an elliptical notch, a rectangular notch, a recess or a groove shape, for example. The position where the correction mechanism is provided on the carrier C of the present embodiment is not limited to the outer circumferential wall surface C13 as shown in FIG. 3A, and may be the bottom surface C11 or the inner circumferential wall surface C14, for example.

FIG. 4A to FIG. 4E are a plan view and vertical cross-sectional views in a vertical direction of a transfer protocol for the wafer WF and the carrier C within the reaction chamber 111. When the carrier C supporting the wafer WF is transported into the reaction chamber 111 of the reaction furnace 11, in a state where the carrier C rests on the first blade 123 of the first robot 121 as illustrated in the plan view of FIG. 4A, the wafer WF is transported to above the susceptor 112 as illustrated in FIG. 4B. Next, the carrier C is temporarily lifted by three or more carrier lifting pins 115 provided relatively to the susceptor 112 so as to be capable of displacing vertically as illustrated in FIG. 4C, and the first blade 123 is retracted as illustrated in FIG. 4D Then, by raising the susceptor 112 as illustrated in FIG. 4E, the carrier C is placed on the top surface of the susceptor 112.

Conversely, when the CVD film formation treatment in the reaction chamber 111 of the reaction furnace 11 ends and the treated wafer WF is extracted in a state mounted on the carrier C, first, from the state illustrated in FIG. 4E, the susceptor 112 is lowered and supports the carrier C with only the carrier lifting pins 115 as illustrated in FIG. 4D. Next, the first blade 123 is advanced between the carrier C and the susceptor 112 as illustrated in FIG. 4C, and then the three carrier lifting pins 115 are lowered to rest the carrier C on the first blade 123 as illustrated in FIG. 4B, and the hand of the first robot 121 is operated. In this way, the wafer WF that has completed the CVD film formation treatment can be extracted in a state mounted on the carrier C.

In the vapor deposition device 1 of the present embodiment, the wafer WF is transported between the load-lock chamber 13 and the reaction chamber 111 in a state supported on the carrier C. To sequentially perform the CVD film formation treatment on wafers WF in the vapor deposition device 1, an after-treatment wafer WF must be removed from the carrier C and a before-treatment wafer WF must be placed on the carrier C. Therefore, a holder 17 is provided to the load-lock chamber 13.

The holder 17 is a support body for supporting the carrier C at two vertical levels in the load-lock chamber 13. The wafer WF may or may not be placed on the carrier C supported by the holder 17. In the vapor deposition device 1 of the present embodiment, the wafer WF is transported between the load-lock chamber 13 and the reaction chamber 111 in a state resting on the carrier C. Accordingly, the before-treatment wafer WF is placed on the carrier C supported by the holder 17 in the load-lock chamber 13. In addition, the after-treatment wafer WF is removed from the carrier C supported by the holder 17 in the load-lock chamber 13.

FIG. 5A is a plan view illustrating an exemplary holder 17 of the present embodiment that is provided to the load-lock chamber 13 and FIG. 5B is a vertical cross-sectional view of the holder 17 of FIG. 5A, including the wafer WF and the carrier C, when viewed in a front view. The holder 17 of the present embodiment includes a holder base 171, a first holder 172, a second holder 173, and wafer lifting pins 174.

The holder base 171 is a base for supporting the holder 17. The holder base 171 is fixed to the load-lock chamber 13.

The first holder 172 and the second holder 173 are support bodies for supporting the carrier C. The first holder 172 and the second holder 173 support two carriers C at two vertical levels, and are capable of lifting and lowering vertically relative to the holder base 171. The first holder 172 and the second holder 173 (in the plan view of FIG. 5A, the second holder 173 is obscured by the first holder 172 and therefore only the first holder 172 is depicted) have projections for supporting the carrier C at four points. The number of points where the first holder 172 and second holder 173 support the carrier C is not particularly limited and may be four points or more. One carrier C is placed on the first holder 172 and another carrier C is placed on the second holder 173. The carrier C that rests on the second holder 173 is inserted into a gap between the first holder 172 and the second holder 173.

The wafer lifting pin 174 is a support body for supporting the wafer WF. The wafer lifting pin 174 is capable of lifting and lowering vertically relative to the holder base 171 and the wafer WF supported by the carrier C is displaced vertically relative to the carrier C when the holder 17 is viewed in a front view. The holder 17 shown in FIG. 5A includes three wafer lifting pins 174, but the number of the wafer lifting pins 174 is not particularly limited and may be four pins or more. The shape of the wafer lifting pin 174 is not particularly limited and may be thicker or thinner than the pins illustrated in FIG. 5B. The shape of forefront end of the wafer lifting pin 174 that contacts the wafer WF may be rounder or more pointed than the forefront end of the pins illustrated in FIG. 5B.

Further, when the vapor deposition device 1 according to the present embodiment is viewed in plan view, the holder 17 according to the present embodiment is provided with at least one correction mechanism that corrects the position of the carrier C in the rotation direction along the circumferential direction of the wafer. A second engagement portion 177 of FIG. 5A is an exemplary correction mechanism of the present embodiment. The second engagement portion 177 is a projection provided to a first holder support body 175 as illustrated in FIG. 5A. FIG. 5C(A) is a plan view and FIG. 5C(B) is a vertical cross-sectional view illustrating the second engagement portion 177 of FIG. 5A. As shown in FIGS. 5C(A) and (B), the second engagement portion 177 includes a base 177a and a projection 177b. The base 177a is cylindrical and the projection 177b is a cylindrical shape thinner than the base 177a with a round head. The shapes of the base 177a and the projection 177b are not limited to those shown in FIGS. 5C(A) and (B), and may be elliptical or rectangular, for example. In addition, the projection 177b may be integrated with the base 177a.

In addition, the shape of the correction mechanism of the present embodiment is not limited to the projection shown in FIGS. 5C(A) and (B), and may be a convex, recess or groove shape, for example. The number and positioning of the correction mechanism of the present embodiment, such as the second engagement portion 177, are not particularly limited as long as the position of the carrier C in the rotation direction can be determined when the carrier C is viewed in plan view. For example, FIG. 6A is a plan view illustrating another exemplary holder 17 of the present embodiment and FIG. 6B is a vertical cross-sectional view of the holder 17 of FIG. 6A including the wafer WF and the carrier C, when viewed in a front view. A second engagement portion 177′ of the holder 17 in FIG. 6A has the same shape as the one illustrated in FIGS. 5C(A) and (B), but the positioning in FIG. 6A forms a substantially isosceles triangle, while the positioning in FIG. 5A forms a substantially trapezoidal shape when viewed in plan view.

Also, in FIG. 5A, the second engagement portion 177 is provided to the first holder support body 175, but the second engagement portion 177 may be provided to both the first holder support body 175 and the second holder support body 176, or to the second holder support body 176 only. In a case where the correction mechanism of the present embodiment, such as the second engagement portion 177, is provided only to the second holder support body 176, the positioning in the rotation direction in plan view is performed when the carrier C is placed on the second holder 173, which is the lower level of the holder. In this example, the first holder support body 175 and the second holder support body 176 are the support body supporting the first holder 172 and the second holder 173 respectively, and go up and down vertically together with the first holder 172 and the second holder 173 relative to the holder base 171.

The number of the correction mechanisms of the present embodiment, such as the first engagement portions C15, C15′ and the second engagement portions 177, 177′, is not particularly limited, however, preferably at least two correction mechanisms are provided to regulate clockwise rotation and counterclockwise rotation of the carrier C along the circumferential direction of the wafer using a pair of correction mechanisms. In addition, when the vapor deposition device 1 is viewed in plan view, the correction mechanism according to the present embodiment preferably corrects positioning of the carrier C in the vertical direction as well as the left and right direction. This is because, when the position in the vertical, left and right, and rotation directions can be corrected with a single correction mechanism, the number of correction mechanisms required for correcting the position of the carrier C can be constrained.

FIG. 7 is a plan view and vertical cross-sectional views of a transfer protocol for the wafer WF and carrier C in the load-lock chamber 13 and depicts a protocol in which the before-treatment wafer WF rests on the carrier C in a state where the carrier C is supported by the first holder 172, as illustrated in FIG. 7B. In other words, the second robot 141 that is provided to the factory interface 14 loads one wafer WF that is stored in the wafer storage container 15 onto the second blade 143 and transports the wafer WF via the first door 131 of the load-lock chamber 13 to a top portion of the holder 17, as illustrated FIG. 7B. Next, as illustrated in FIG. 7C, the three wafer lifting pins 174 are raised relative to the holder base 171 and temporarily hold up the wafer WF, and the second blade 143 is retracted as illustrated in FIG. 7D. The three wafer lifting pins 174 are provided in positions that do not interfere with the second blade 143, as illustrated in the plan view of FIG. 7A. Next, as illustrated in FIGS. 7D and 7E, the three wafer lifting pins 174 are lowered and the first holder 172 and the second holder 173 are raised, whereby the wafer WF is placed on the carrier C.

Conversely, when the after-treatment wafer WF transported to the load-lock chamber 13 in a state resting on the carrier C is transported to the wafer storage container 15, the three wafer lifting pins 174 are raised as illustrated in FIG. 7D and the first holder 172 and the second holder 173 are lowered from the state illustrated in FIG. 7E, the wafer WF is supported by only the wafer lifting pins 174, and the second blade 143 is advanced between the carrier C and the wafer WF as illustrated in FIG. 7C, after which the three wafer lifting pins 174 are lowered to load the wafer WF on the second blade 143 as illustrated in FIG. 7B, and the hand of the second robot 141 is operated. In this way, the wafer WF for which treatment has ended can be taken out of the carrier C and into the wafer storage container 15. In the state illustrated in FIG. 7E, the wafer WF for which treatment has ended is transported to the first holder 172 in a state resting on the carrier C, but the wafer WF can be taken out of the carrier C and into the wafer storage container 15 with a similar protocol when the wafer WF is transported to the second holder 173, as well.

In the vapor deposition device 1 of the present embodiment, the first blade 123 is mounted on a distal end of the first robot 121's hand. A first recess 124 is formed in the first blade 123 for transporting the empty carrier C or with the wafer WF placed thereon. In the vapor deposition device 1 of the present embodiment, the first blade 123 and the first recess 124 have a shape of the correction mechanism, such as the first engagement portions C15, C15′ and the second engagement portions 177, 177′, and a shape corresponding to the arrangement thereof.

For example, FIG. 8A is a plan view illustrating an exemplary first blade 123 and, as shown in FIG. 4A, is a plan view illustrating an exemplary first blade 123 for transporting the carrier C illustrated in FIG. 2A. FIG. 8B is a vertical cross-sectional view of the first blade 123 when viewed from a side direction, including the carrier C and the wafer WF shown in FIG. 2A. The first blade 123 of the present embodiment has the first recess 124 formed on one surface of a main body which is in a plate-like strip shape, the first recess 124 having a shape corresponding to the outer circumferential wall surface C13 and the first engagement portion C15 of the carrier C. The shape of the first recess 124 is formed slightly larger than the outer periphery of the outer circumferential wall surface C13 and the first engagement portion C15 of the carrier C when viewed in plan view such that the carrier C fits to the first recess 124 of the first blade 123. The first robot 121 places the carrier C on the first recess 124 when transporting the empty carrier C or with the wafer WF placed thereon.

The first engagement portion C15 and the second engagement portion 177 of the present embodiment correct the position of the carrier C in the rotation direction along the circumferential direction of the wafer WF by engaging with each other when the carrier C is placed on the holder 17. For example, the first engagement portion C15 of the carrier C illustrated in FIG. 2A corrects the position of the carrier C in the rotation direction by engaging with the second engagement portion 177 of the holder 17 illustrated in FIG. 5A. FIG. 9A is a plan view of the carrier C and holder 17 when the carrier C illustrated in FIG. 2A is placed on the holder 17 illustrated in FIG. 5A; the first engagement portion C15 and the second engagement portion 177 are engaged; and the position of the carrier C in the rotation direction is corrected. In addition, when the carrier C is placed on the holder 17 for example, the first engagement portion C15′ of the carrier C illustrated in FIG. 3A, by engaging with the second engagement portion 177′ of the holder 17 illustrated in FIG. 6A, corrects the position of the carrier C in the rotation direction along the circumferential direction of the wafer WF. FIG. 9B is a plan view of the carrier C and holder 17 when the carrier C illustrated in FIG. 3A is placed on the holder 17 illustrated in FIG. 6A; the first engagement portion C15′ and the second engagement portion 177′ are engaged; and the position of the carrier C in the rotation direction is corrected.

Further, when correcting the position of the carrier C in the rotation direction by engaging the first engagement portion C15 of the carrier C with the second engagement portion 177 of the holder 17, the second engagement portion 177 of the present embodiment preferably includes an engagement surface Fa that engages with the first engagement portion C15, a rotation surface Fb that rotates the carrier C relatively to the holder 17, and a positioning surface Fc that determines a correction position of the carrier C relative to the holder 17. By providing the engagement surface Fa and the rotation surface Fb, the carrier C can be guided to the positioning surface Fc when the first engagement portion C15 and the second engagement portion 177 are loosely fit together and the carrier C can be further inhibited from shifting from the predetermined position.

FIG. 10A is a plan view illustrating the second engagement portion 177 of the present embodiment, and FIG. 10B is a vertical cross-sectional view. For example, as shown in FIG. 10B, the second engagement portion 177 can provide the projection 177b with the engagement surface Fa and the rotation surface Fb, and provide the positioning surface Fc on the top surface of the base 177a. The rotation surface Fb of the present embodiment preferably has a size to allow the carrier C to sufficiently rotate relatively to the holder 17 and correct the position in the rotation direction when the vapor deposition device 1 is viewed in plan view. In addition, when the second engagement portion 177 of the present embodiment is viewed in a side view, a tilt of the rotation surface Fb preferably has an angle for the carrier C to be able to rotate relatively to the holder 17. A tilt α formed by the engagement surface Fa and the rotation surface Fb according to the present embodiment may be 105° to 165°, 120° to 150°, or 130° to 140°.

FIGS. 11 to 13 show a positional relationship of the first engagement portion C15 and the second engagement portion 177 when the carrier C is placed on the holder 17, where the first engagement portion C15 of the carrier C illustrated in FIG. 2A engages with the second engagement portion 177 illustrated in FIGS. 10A and B and corrects the position of the carrier C in the rotation direction. FIGS. 11A, 12A, and 13A are plan views illustrating the carrier C shown in FIG. 2A and the second engagement portion 177 illustrated in FIGS. 10A and B, and FIGS. 11B, 12B, and 13B are vertical cross-sectional views of the holder 17 when viewed in a front view.

The carrier C is placed on the holder 17 by the first robot 121 to which the first blade 123 is mounted. As illustrated in FIG. 5B, the carrier C approaches the holder 17 from above when the carrier C is placed on the holder 17. Therefore, the first engagement portion C15 first engages with the engagement surface Fa of the second engagement portion 177, as illustrated in FIG. 11B for example. In FIG. 11B, the first engagement portion C15 is loosely fit to the second engagement portion 177, and even when the first engagement portion C15 is engaged with the engagement surface Fa of the second engagement portion 177, the carrier C can be moved in the vertical direction. Further, even when the first engagement portion C15 is in contact with the engagement surface Fa of the second engagement portion 177, the carrier C can be moved in the vertical direction by sliding the first engagement portion C15 on the engagement surface Fa.

When the position of the carrier C is lowered, the first engagement portion C15 passes the engagement surface Fa of the second engagement portion 177 and engages with the rotation surface Fb of the second engagement portion 177, as illustrated in FIG. 12B for example. In FIG. 12B, the left side end of the first engagement portion C15 is in contact with the rotation surface Fb of the second engagement portion 177 arranged on the left side. The rotation surface Fb has a slope, and the carrier C is displaced downward while the left side end of the first engagement portion C15 slides on the rotation surface Fb along the slope. At this time, the carrier C rotates in an arrow A direction (clockwise direction) in FIG. 12A. With the rotation of the carrier C due to the slope of the rotation surface Fb, the carrier C of the present embodiment can correct position in the rotation direction.

The left side end of the first engagement portion C15 moves along the rotation surface Fb, sliding on the rotation surface Fb, while engaged with the second engagement portion 177 arranged on the left side. Accordingly, the carrier C moves toward the predetermined position while rotating in an arrow A direction in FIG. 13A. When the first engagement portion C15 passes the rotation surface Fb of the second engagement portion 177 and the carrier C is placed on the holder 17, the carrier C of the present embodiment is placed on the positioning surface Fc which is the predetermined position of the carrier C as illustrated in FIGS. 13A and B, for example.

As shown in FIG. 10, the second engagement portion 177 may be provided with the engagement surface Fa, the rotation surface Fb, and the positioning surface Fc, or a surface similar to these surfaces may be provided to the first engagement portion C15. For example, FIG. 14A is a bottom view of yet another exemplary carrier C of the present embodiment, and FIG. 14B is a vertical cross-sectional view. The carrier C illustrated in FIG. 14A is provided with the first engagement portion C15′. The first engagement portion C15′ includes an engagement rotation surface Fa′ in which the engagement surface Fa and the rotation surface Fb are configured on the same plane, and also includes a positioning surface Fc′. In this way, the engagement surface Fa and the rotation surface Fb may be configured on the same plane in the correction mechanism according to the present embodiment. Accordingly, the size of the correction mechanism increasing relatively to the carrier C can be inhibited.

The engagement rotation surface Fa′ of the present embodiment preferably has a size that allows the carrier C to sufficiently rotate relatively to the holder 17 and correct the position in the rotation direction when the vapor deposition device 1 is viewed in plan view. In addition, when the carrier C of present embodiment is viewed in a side view, a tilt of the engagement rotation surface Fa′ is preferably at an angle where the carrier C can rotate relatively to the holder 17. A tilt α′ formed by the engagement rotation surface Fa′ and the positioning surface Fc′ according to the present embodiment may be 105° to 165°, 120° to 150° , or 130° to 140°, for example.

FIGS. 15 to 17 show a positional relationship of the first engagement portion C15′ and a second engagement portion 177″ when the carrier C is placed on the holder 17, where the first engagement portion C15′ of the carrier C illustrated in FIG. 14 engages with the second engagement portion 177″ which has a shape corresponding to the first engagement portion C15′ and the position of the carrier C in the rotation direction is corrected. FIGS. 15A, 16A, and 17A are bottom views illustrating the carrier C and the second engagement portion 177″ illustrated in FIG. 14, and FIGS. 15B, 16B, and 17B are front views.

The carrier C is placed on the holder 17 by the first robot 121 to which the first blade 123 is mounted. As illustrated in FIG. 5B, the carrier C approaches the holder 17 from above when the carrier C is placed on the holder 17. Therefore, the second engagement portion 177″ first engages with the engagement rotation surface Fa′ on the left side of the first engagement portion C15′, as illustrated in FIGS. 15A and B for example. In FIG. 15B, the second engagement portion 177″ is loosely fit to the first engagement portion C15′ and even when engaged with the engagement rotation surface Fa′ of the first engagement portion C15′, the carrier C can be moved in the vertical direction. Further, even when the second engagement portion 177″ is in contact with the engagement rotation surface Fa′ of the first engagement portion C15′, the carrier C can be moved in the vertical direction by sliding the second engagement portion 177″ on the engagement rotation surface Fa′.

In addition, in the first engagement portion C15′ of the carrier C according to the present embodiment, the engagement surface Fa and the rotation surface Fb are formed as the same engagement rotation surface Fa′, and therefore the carrier C starts to rotate when the first engagement portion C15′ is engaged with the second engagement portion 177″. For example, in FIG. 15A, the carrier C is displaced downward toward the holder, and thereby the second engagement portion 177″ slides on the engagement rotation surface Fa′ on the left side of the first engagement portion C15′, as illustrated in FIG. 15B. By sliding the second engagement portion 177″ on the engagement rotation surface Fa′, the carrier C starts to rotate in an arrow A′ direction in FIG. 15A.

When the position of the carrier C is lowered, as illustrated in FIG. 16A for example, the second engagement portion 177″ contacts the outer circumferential wall surface C13 of the of the carrier C and thereby the rotation of the carrier C in the arrow A′ direction stops. As shown in FIG. 16A, the carrier C which stopped rotating in the arrow A′ direction is moved downward by sliding the second engagement portion 177″ on the engagement rotation surface Fa′, as illustrated in FIG. 16B for example. The second engagement portion 177″, as illustrated in FIGS. 17A and B for example, fits to the positioning surface Fc′ once the second engagement portion 177″ passes the engagement rotation surface Fa′. By fitting the second engagement portion 177″ to the positioning surface Fc′, the carrier C is placed at the predetermined position of the holder 17.

Next, a protocol is described for handling the carrier C and the wafer WF prior to creating the epitaxial film (hereafter referred to simply as “before-treatment”) and after creating the epitaxial film (hereafter referred to simply as “after-treatment”) in the vapor deposition device 1 according to the present embodiment. FIGS. 18A to 18D are schematic views illustrating a handling protocol for the wafer and the carrier in the vapor deposition device of the present embodiment and correspond to the wafer storage container 15, the load-lock chamber 13, and the reaction furnace 11 on one side in FIG. 1; a plurality of wafers W1, W2, W3 . . . (for example, a total of 25 wafers) are stored in the wafer storage container 15 and treatment is initiated in that order.

Step S0 in FIG. 18A shows a standby state from which treatment using the vapor deposition device 1 is to begin, and has the plurality of wafers W1, W2, W3 . . . (for example, a total of 25 wafers) stored in the wafer storage container 15, has an empty carrier C1 supported by the first holder 172 of the load-lock chamber 13, has an empty carrier C2 supported by the second holder 173, and has an inert gas atmosphere in the load-lock chamber 13.

In the next step S1, the second robot 141 loads the wafer W1 that is stored in the wafer storage container 15 onto the second blade 143, opens the first door 131 of the load-lock chamber 13, and transfers the wafer W1 to the carrier C1 that is supported by the first holder 172. The protocol for this transfer was described with reference to FIG. 7.

In the next step S2, the first door 131 of the load-lock chamber 13 is closed and, in a state where the second door 132 is also closed, the interior of the load-lock chamber 13 again undergoes gas exchange to the inert gas atmosphere. Then, the second door 132 is opened, the carrier C1 is loaded onto the first blade 123 of the first robot 121, the gate valve 114 of the reaction furnace 11 is opened, and the carrier C1 on which the wafer W1 is mounted is transferred through the gate valve 114 to the susceptor 112. The protocol for this transfer was described with reference to FIG. 4. In steps S2 to S4, the CVD film creation process is performed on the wafer W1 in the reaction furnace 11.

In other words, the carrier C1 on which the before-treatment wafer W1 is mounted is transferred to the susceptor 112 of the reaction chamber 111 and the gate valve 114 is closed, and after waiting a predetermined amount of time, the gas supply device 113 supplies hydrogen gas to the reaction chamber 111, giving the reaction chamber 111 a hydrogen gas atmosphere. Next, the wafer W1 in the reaction chamber 111 is heated to a predetermined temperature by the heat lamp and pretreatment such as etching or heat treatment is performed as necessary, after which the gas supply device 113 supplies raw material gas or dopant gas while controlling the flow volume and/or supply time. This creates a CVD film on the surface of the wafer W1. Once the CVD film is formed, the gas supply device 113 once again supplies the reaction chamber 111 with hydrogen gas and the reaction chamber 111 undergoes gas exchange to a hydrogen gas atmosphere, after which the protocol stands by for a predetermined amount of time.

While the reaction furnace 11 is treating the wafer W1 in steps S2 to S4 in this way, the second robot 141 extracts the next wafer W2 from the wafer storage container 15 and prepares for the next treatment. Prior to this, in step S3 in the present embodiment, the second door 132 of the load-lock chamber 13 is closed, and in a state where the first door 131 is also closed, the interior of the load-lock chamber 13 undergoes gas exchange to an inert gas atmosphere. Then, the second door 132 is opened, the carrier C2 supported by the second holder 173 is transferred to the first holder 172 by the first robot 121, and the second door 132 is closed. Subsequently, in step S4, the second robot 141 loads the wafer W2 that is stored in the wafer storage container 15 onto the second blade 143, the first door 131 is opened, and the wafer W2 is transferred to the carrier C2 that is supported by the first holder 172 of the load-lock chamber 13.

In this way, in the present embodiment, step S3 is added and the before-treatment wafer WF that was stored in the wafer storage container 15 is mounted on the first holder 172, which is the topmost-level holder of the holder 17 of the load-lock chamber 13. This is for the following reasons. Specifically, as illustrated in step S2, when the empty carrier C2 on which the next wafer W2 is to be mounted is supported by the second holder 173, once the wafer W2 is mounted thereon, there is a possibility that the carrier C1 on which the after-treatment wafer W1 is mounted may be transferred to the first holder 172. The carrier C of the vapor deposition device 1 according to the present embodiment is transported to the reaction chamber 111, and therefore the carrier C is a factor in particle production, and when the carrier C1 is supported above the before-treatment wafer W2, dust may fall on the before-treatment wafer W2. Therefore, step S3 is added and the empty carrier C2 is transferred to the first holder 172 so that the before-treatment wafer WF is mounted on the topmost-level holder (first holder 172) of the holder 17 of the load-lock chamber 13. When the correction mechanism of the present embodiment is provided to the first holder 172, which is on the top level of the holder 17, in step S3, the position of the carrier C in the rotation direction is corrected when the carrier C is transferred from the second holder 173 to the first holder 172.

In step S5, the first door 131 of the load-lock chamber 13 is closed and, in a state where the second door 132 is also closed, the interior of the load-lock chamber 13 undergoes gas exchange to an inert gas atmosphere. Then, the gate valve 114 of the reaction furnace 11 is opened, the first blade 123 of the first robot 121 is inserted into the reaction chamber 111 and is loaded with the carrier C1 on which the after-treatment wafer W1 is mounted, the carrier C1 is withdrawn from the reaction chamber 111, and the gate valve 114 is closed, after which the second door 132 is opened and the carrier C1 is transferred to the second holder 173 of the load-lock chamber 13. When the correction mechanism of the present embodiment is provided to the second holder 173, which is on the lower level of the holder 17, in step S5, the position of the carrier C in the rotation direction is corrected when the carrier C is transferred from the reaction chamber 111 to the second holder 173. Subsequently, the carrier C2 supported by the first holder 172 is loaded onto the first blade 123 of the first robot 121 and, as illustrated in step S6, the gate valve 114 is opened and the carrier C2 on which the before-treatment wafer W2 is mounted is transferred through the wafer transfer chamber 12 to the susceptor 112 of the reaction furnace 11.

In steps S6 to S9, the CVD film creation process is performed on the wafer W2 in the reaction furnace 11. In other words, the carrier C2 on which the before-treatment wafer W2 is mounted is transferred to the susceptor 112 of the reaction chamber 111 and the gate valve 114 is closed, and after waiting a predetermined amount of time, the gas supply device 113 supplies hydrogen gas to the reaction chamber 111, giving the reaction chamber 111 a hydrogen gas atmosphere. Next, the wafer W2 in the reaction chamber 111 is heated to a predetermined temperature by the heat lamp and pretreatment such as etching or heat treatment is performed as necessary, after which the gas supply device 113 supplies raw material gas or dopant gas while controlling the flow volume and/or supply time. This creates a CVD film on the surface of the wafer W2. Once the CVD film is formed, the gas supply device 113 once again supplies the reaction chamber 111 with hydrogen gas and the reaction chamber 111 undergoes gas exchange to a hydrogen gas atmosphere, after which the protocol stands by for a predetermined amount of time.

While the reaction furnace 11 is treating the wafer W2 in steps S6 to S9 in this way, the second robot 141 stores the after-treatment wafer W1 in the wafer storage container 15 and also extracts the next wafer W3 from the wafer storage container 15 and prepares for the next treatment. In other words, in step S7, the second door 132 of the load-lock chamber 13 is closed, and in a state where the first door 131 is also closed, the interior of the load-lock chamber 13 undergoes gas exchange to an inert gas atmosphere. Then, the first door 131 is opened, the second robot 141 loads the after-treatment wafer W1 onto the second blade 143 from the carrier C1 supported by the second holder 173 and, as illustrated in step S8, the after-treatment wafer W1 is stored in the wafer storage container 15. Subsequently, similarly to step S3 described above, in step S8, the first door 131 of the load-lock chamber 13 is closed, and in a state where the second door 132 is also closed, the interior of the load-lock chamber 13 undergoes gas exchange to an inert gas atmosphere. Then, the second door 132 is opened, and the carrier C1 supported by the second holder 173 is transferred to the first holder 172 by the first robot 121. When the correction mechanism of the present embodiment is provided to the first holder 172, which is on the top level of the holder 17, in step S8, the position of the carrier C in the rotation direction is corrected when the carrier C is transferred to the first holder 172.

Subsequently, in step S9, the second door 132 of the load-lock chamber 13 is closed, and in a state where the first door 131 is also closed, the interior of the load-lock chamber 13 undergoes gas exchange to an inert gas atmosphere. Then, the second robot 141 loads the wafer W3 that is stored in the wafer storage container 15 onto the second blade 143 and, as illustrated in step S9, the first door 131 is opened and the wafer W3 is transferred to the carrier C1 that is supported by the first holder 172 of the load-lock chamber 13.

In step S10, similarly to step S5 described above, the first door 131 of the load-lock chamber 13 is closed, and in a state where the second door 132 is also closed, the interior of the load-lock chamber 13 undergoes gas exchange to an inert gas atmosphere. Then, the gate valve 114 of the reaction furnace 11 is opened, the first blade 123 of the first robot 121 is inserted into the reaction chamber 111 and is loaded with the carrier C2 on which the after-treatment wafer W2 is mounted, and the gate valve 114 is closed, after which the second door 132 is opened and the carrier C2 is transferred from the reaction chamber 111 to the second holder 173 of the load-lock chamber 13. Subsequently, the carrier C1 supported by the first holder 172 is loaded onto the first blade 123 of the first robot 121 and, as illustrated in step S11, the carrier C1 on which the before-treatment wafer W3 is mounted is transferred through the wafer transfer chamber 12 to the susceptor 112 of the reaction furnace 11.

In step S10, similarly to step S7 described above, the second door 132 of the load-lock chamber 13 is closed, and in a state where the first door 131 is also closed, the interior of the load-lock chamber 13 undergoes gas exchange to an inert gas atmosphere. Then, the first door 131 is opened, the second robot 141 loads the after-treatment wafer W2 onto the second blade 143 from the carrier C2 that is supported on the second holder 173 and, as illustrated in step S11, the after-treatment wafer W2 is stored in the wafer storage container 15. Thereafter, the above steps are repeated until treatment for all of the before-treatment wafers WF stored in the wafer storage container 15 ends.

As described above, the vapor deposition device 1 according to the present embodiment can correct the positional offset of the carrier in the rotation direction relative to the wafer by providing the carrier C and the holder 17 with a correction mechanism that corrects the position of the carrier C in the rotation direction along the circumferential direction of the wafer WF. In this case, by providing a pair of correction mechanisms that regulate a clockwise rotation and a counterclockwise rotation of the carrier C, the positional offset of the carrier C in the rotation direction can be still further corrected. In addition, when the vapor deposition device 1 is viewed in plan view, the correction mechanism according to the present embodiment corrects positioning of the carrier C in the vertical direction as well as the left and right direction, and thereby the number of correction mechanisms required for correcting the position of the carrier C can be constrained. Further, by not providing the holder 17 with the correction mechanism on the topmost-level holder and providing the correction mechanism on at least one of the levels from the second-level-from-the-top and below, a carrier C which has already had its position in the rotation direction corrected by the correction mechanism can avoid having its position corrected again on the topmost-level holder.

In addition, the correction mechanism of the present embodiment can still further correct the positional offset of the carrier C in the rotation direction by including the first engagement portions C15, C15′ provided to the carrier C, and the second engagement portions 177, 177′, 177″ provided to the holder 17. Further, by providing the engagement surface Fa where the second engagement portion 177 engages with the first engagement portion C15, the rotation surface Fb that rotates the carrier C relatively to the holder 17, and the positioning surface Fc that determines a correction position of the carrier C relative to the holder 17, the carrier C can be guided to the positioning surface Fc when the first engagement portion C15 and the second engagement portion 177 are loosely fit together and the carrier C can be further corrected from shifting from the predetermined position. Further, by providing the engagement rotation surface Fa′ that rotates the carrier C relatively to the holder 17 by engaging the first engagement portion C15′ with the second engagement portion 177″, and the positioning surface Fc′ that determines the correction position of the carrier C relative to the holder 17, the carrier C can be guided to the positioning surface Fc′ when the first engagement portion C15′ and the second engagement portion 177″ are loosely fit together and the carrier C can be further corrected from shifting from the predetermined position. In this case, the engagement surface Fa and the rotation surface Fb are configured as the engagement rotation surface Fa′ on the same plane, and thereby the correction mechanism according to the present embodiment increases in size relative to the carrier C and can suppress influences on the temperature of the carrier C and the quality of the CVD film being formed.

### DESCRIPTION OF REFERENCE NUMERALS

1 . . . Vapor deposition device

11 . . . Reaction furnace

111 . . . Reaction chamber

112 . . . Susceptor

113 . . . Gas supply device

114 . . . Gate valve

115 . . . Carrier lifting pin

12 . . . Wafer transfer chamber

121 . . . First robot

122 . . . First robot controller

123 . . . First blade

124 . . . First recess

13 . . . Load-lock chamber

131 . . . First door

132 . . . Second door

14 . . . Factory interface

141 . . . Second robot

142 . . . Second robot controller

143 . . . Second blade

15 . . . Wafer storage container

16 . . . Integrated controller

17 . . . Holder

171 . . . Holder base

172 . . . First holder

173 . . . Second holder

174 . . . Wafer lifting pin

175 . . . First holder support body

176 . . . Second holder support body

177, 177′, 177″ . . . Second engagement portion

177a . . . Base

177b . . . Projection

Fa . . . Engagement surface

Fb . . . Rotation surface

Fc . . . Positioning surface

α . . . Tilt

C . . . Carrier

C11 . . . Bottom surface

C12 . . . Top surface

C13 . . . Outer circumferential wall surface

C14 . . . Inner circumferential wall surface

C15, C15′ . . . First engagement portion

Fa′ . . . Engagement rotation surface

Fc′ . . . Positioning surface

α′ . . . Tilt

WF . . . Wafer

1. A vapor deposition device which uses a ring-shaped carrier that supports a wafer to form a CVD film on the wafer, wherein
the vapor deposition device includes a load-lock chamber provided with a holder for supporting the carrier, and
the carrier and holder are provided with a correction mechanism that corrects a position of the carrier in a rotation direction along a circumferential direction of the wafer.

2. The vapor deposition device according to claim 1, wherein the correction mechanism includes a pair of correction mechanisms to regulate clockwise rotation and counterclockwise rotation of the carrier.

3. The vapor deposition device according to claim 1, wherein the correction mechanism includes a correction mechanism that corrects a position of the carrier in vertical direction as well as left and right direction, when the device is viewed in a plan view.

4. The vapor deposition device according to claim 1, wherein the correction mechanism includes a first engagement portion provided to the carrier and a second engagement portion provided to the holder.

5. The vapor deposition device according to claim 4, wherein the second engagement portion includes an engagement surface that engages with the first engagement portion, a rotation surface that rotates the carrier relatively to the holder, and a positioning surface that determines a correction position of the carrier relative to the holder.

6. The vapor deposition device according to claim 4, wherein the first engagement portion includes an engagement surface that engages with the second engagement portion, a rotation surface that rotates the carrier relatively to the holder, and a positioning surface that determines a correction position of the carrier relative to the holder.

7. The vapor deposition device according to claim 5, wherein the engagement surface and the rotation surface are configured on the same plane.

8. The vapor deposition device according to claim 1, wherein the holder supports at least two carriers vertically, and the correction mechanism is not provided to the topmost-level holder.

9. The vapor deposition device according to claim 1, wherein the CVD film is a silicon epitaxial film.

10. The vapor deposition device according to claim 1, wherein a plurality of before-treatment wafers are transported from a wafer storage container, through a factory interface, the load-lock chamber, and a wafer transfer chamber, to a reaction chamber that forms the CVD film on the wafer, in that order,
a plurality of after-treatment wafers are also transported from the reaction chamber, through the wafer transfer chamber, load-lock chamber, and factory interface, to the wafer storage container, in that order,
the load-lock chamber communicates with the factory interface via a first door and also communicates with the wafer transfer chamber via a second door,
the wafer transfer chamber communicates, via a gate valve, with the reaction chamber,
the wafer transfer chamber is provided with a first robot that deposits the before-treatment wafer transported into the load-lock chamber into the reaction chamber in a state where the before-treatment wafer is supported by the carrier and also, for the after-treatment wafer for which treatment in the reaction chamber has ended, withdraws the after-treatment wafer from the reaction chamber in a state where the after-treatment wafer is supported by the carrier and transports the wafer to the load-lock chamber, and the factory interface is provided with a second robot that extracts the before-treatment wafer from the wafer storage container and supports the wafer with the carrier that is standing by in the load-lock chamber, and also stores in the wafer storage container the after-treatment wafer supported by the carrier that has been transported to the load-lock chamber.

11. The vapor deposition device according to claim 5, wherein a plurality of before-treatment wafers are transported from a wafer storage container, through a factory interface, the load-lock chamber, and a wafer transfer chamber, to a reaction chamber that forms the CVD film on the wafer, in that order,
a plurality of after-treatment wafers are also transported from the reaction chamber, through the wafer transfer chamber, load-lock chamber, and factory interface, to the wafer storage container, in that order,
the load-lock chamber communicates with the factory interface via a first door and also communicates with the wafer transfer chamber via a second door,
the wafer transfer chamber communicates, via a gate valve, with the reaction chamber,
the wafer transfer chamber is provided with a first robot that deposits the before-treatment wafer transported into the load-lock chamber into the reaction chamber in a state where the before-treatment wafer is supported by the carrier and also, for the after-treatment wafer for which treatment in the reaction chamber has ended, withdraws the after-treatment wafer from the reaction chamber in a state where the after-treatment wafer is supported by the carrier and transports the wafer to the load-lock chamber, and
the factory interface is provided with a second robot that extracts the before-treatment wafer from the wafer storage container and supports the wafer with the carrier that is standing by in the load-lock chamber, and also stores in the wafer storage container the after-treatment wafer supported by the carrier that has been transported to the load-lock chamber.

12. The vapor deposition device according to claim 6, wherein a plurality of before-treatment wafers are transported from a wafer storage container, through a factory interface, the load-lock chamber, and a wafer transfer chamber, to a reaction chamber that forms the CVD film on the wafer, in that order,
a plurality of after-treatment wafers are also transported from the reaction chamber, through the wafer transfer chamber, load-lock chamber, and factory interface, to the wafer storage container, in that order,
the load-lock chamber communicates with the factory interface via a first door and also communicates with the wafer transfer chamber via a second door,
the wafer transfer chamber communicates, via a gate valve, with the reaction chamber,
the wafer transfer chamber is provided with a first robot that deposits the before-treatment wafer transported into the load-lock chamber into the reaction chamber in a state where the before-treatment wafer is supported by the carrier and also, for the after-treatment wafer for which treatment in the reaction chamber has ended, withdraws the after-treatment wafer from the reaction chamber in a state where the after-treatment wafer is supported by the carrier and transports the wafer to the load-lock chamber, and
the factory interface is provided with a second robot that extracts the before-treatment wafer from the wafer storage container and supports the wafer with the carrier that is standing by in the load-lock chamber, and also stores in the wafer storage container the after-treatment wafer supported by the carrier that has been transported to the load-lock chamber.

13. The vapor deposition device according to claim 7, wherein a plurality of before-treatment wafers are transported from a wafer storage container, through a factory interface, the load-lock chamber, and a wafer transfer chamber, to a reaction chamber that forms the CVD film on the wafer, in that order,
a plurality of after-treatment wafers are also transported from the reaction chamber, through the wafer transfer chamber, load-lock chamber, and factory interface, to the wafer storage container, in that order,
the load-lock chamber communicates with the factory interface via a first door and also communicates with the wafer transfer chamber via a second door,
the wafer transfer chamber communicates, via a gate valve, with the reaction chamber,
the wafer transfer chamber is provided with a first robot that deposits the before-treatment wafer transported into the load-lock chamber into the reaction chamber in a state where the before-treatment wafer is supported by the carrier and also, for the after-treatment wafer for which treatment in the reaction chamber has ended, withdraws the after-treatment wafer from the reaction chamber in a state where the after-treatment wafer is supported by the carrier and transports the wafer to the load-lock chamber, and
the factory interface is provided with a second robot that extracts the before-treatment wafer from the wafer storage container and supports the wafer with the carrier that is standing by in the load-lock chamber, and also stores in the wafer storage container the after-treatment wafer supported by the carrier that has been transported to the load-lock chamber.

14. The vapor deposition device according to claim 8, wherein a plurality of before-treatment wafers are transported from a wafer storage container, through a factory interface, the load-lock chamber, and a wafer transfer chamber, to a reaction chamber that forms the CVD film on the wafer, in that order,
a plurality of after-treatment wafers are also transported from the reaction chamber, through the wafer transfer chamber, load-lock chamber, and factory interface, to the wafer storage container, in that order,
the load-lock chamber communicates with the factory interface via a first door and also communicates with the wafer transfer chamber via a second door,
the wafer transfer chamber communicates, via a gate valve, with the reaction chamber,
the wafer transfer chamber is provided with a first robot that deposits the before-treatment wafer transported into the load-lock chamber into the reaction chamber in a state where the before-treatment wafer is supported by the carrier and also, for the after-treatment wafer for which treatment in the reaction chamber has ended, withdraws the after-treatment wafer from the reaction chamber in a state where the after-treatment wafer is supported by the carrier and transports the wafer to the load-lock chamber, and
the factory interface is provided with a second robot that extracts the before-treatment wafer from the wafer storage container and supports the wafer with the carrier that is standing by in the load-lock chamber, and also stores in the wafer storage container the after-treatment wafer supported by the carrier that has been transported to the load-lock chamber.
